(19) United States
(12) Patent Application Publication
(10) Pub. No.: US 2021/0014991 A1
(43) Pub. Date: Jan. 14, 2021

(54) SOLID-STATE DISK READ/WRITE APPARATUS AND SOLID-STATE DISK ASSEMBLY THEREOF

(71) Applicant: Bo-Chi CHANG, New Taipei City (TW)

(72) Inventor: Bo-Chi CHANG, New Taipei City (TW)

(21) Appl. No.: 16/507,037

(22) Filed: Jul. 10, 2019

(51) Int. Cl. H05K 5/02; H05K 5/00; H01R 33/94; H01R 33/90; H01R 33/92

(52) U.S. Cl. CPC H05K 5/0278; H05K 5/0047; H01R 33/92; H01R 33/94; H01R 33/90; H05K 5/0247

(57) ABSTRACT

A solid-state disk read/write apparatus includes a solid-state disk assembly (400) and a read/write console (100). The solid-state disk assembly (400) includes a solid-state disk main body (6) and an adapter module (5). The adapter module (5) includes a M.2 connector (52) and a USB connector (53). The solid-state disk main body (6) is electrically connected onto the M.2 connector (52). The read/write console (100) includes a circuit board (2) having a USB engagement connector (21) and a control chip (7) electrically arranged thereon. The solid-state disk assembly (400) uses the USB connector (53) to electrically connect onto the USB engagement connector (21), allowing the solid-state disk main body (6) to electrically connect to the read/write console (100) via the adapter module (5) and the control chip (7). Accordingly, the effects of reducing purchase cost, distributing heat sources and preventing re-insertion of the solid-state disk main body can be achieved.

### BACKGROUND OF THE INVENTION

### Field of the Invention

The technical field relates to a solid-state disk, in particular, to a solid-state disk read/write apparatus and a solid-state disk assembly thereof.

### Description of Related Art

Conventionally, a solid-state disk or solid-state drive (known as “SSD”) main body is mainly secured inside the cassette, and the solid-state disk main body (known as “solid-state disk naked drive”) is electrically inserted into a M.2 connector adopting a M.2 interface configured inside the cassette, thereby achieving the electrical connection of the solid-state disk main body.

However, presently, each solid-state disk cassette requires to be electrically provided with a control chip, and the cost of such control chip is relatively high and it costs approximately 37% of the total cost of a solid-state disk cassette. As a result, the price of currently available solid-state disk cassettes cannot be reduced to a reasonable level. When there is a budget concern, user can only share a cassette equipped with the aforementioned chip among a plurality of solid-state disk main bodies. When a user wishes to use a second solid-state disk main body, it is required to remove the first solid-state disk main body from the cassette, and then install the second solid-state disk main body onto the M.2 connector, and so on.

Despite that users may save the cost from purchasing another cassette, nonetheless, since the gold finger (edge connector) provided on the M.2 insertion portion of the M.2 connector for solid-state disk main body to be attached thereon has a limitation on the number of times of insertion (gold finger tends to start to shown signs of wear and tear after more than 60 times of insertion). Once the number of insertions exceeds the limit, the situation of improper contact is likely to occur, and such drawback has been an issue known to users and manufacturers.

Furthermore, since currently existing solid-state disk cassettes are subject to the heat generated by the solid-state disk main body and the heat generated by the chip, such that the issue of heat accumulation from two heat sources can affect the operation of the solid-state disk main body, and such heat may even shorten the useful lifetime of the solid-state disk main body.

### SUMMARY OF THE INVENTION

An objective of the present invention is to provide a solid-state disk read/write apparatus and a solid-state disk assembly thereof, such that a plurality of solid-state disk assemblies with reduced cost to share one read/write console jointly.

To achieve the aforementioned objective, the present invention provides a solid-state disk read/write apparatus, comprising: a solid-state disk assembly comprising a cassette, a solid-state disk main body and an adapter module; the adapter module secured inside the cassette and having a M.2 connector and a USB connector; the solid-state disk main body electrically inserted onto the M.2 connector for adapting with and electrically connected to the USB connector; and a read/write console having a circuit board, and the circuit board having a control chip and at least one USB engagement connector electrically arranged thereon; wherein when the solid-state disk assembly is removably and electrically inserted onto the USB engagement connector of the read/write console with the USB connector, the solid-state main body is electrically connected to the read/write console via the adapter module and the control chip.

The present invention further provides a solid-state disk assembly, comprising: a cassette; an adapter module comprising an adapter circuit board, a M.2 connector and a USB connector; the adapter circuit board secured inside the cassette; the M.2 connector and the USB connector electrically arranged on the adapter circuit board; the USB connector exposed out of the cassette; and a solid-state disk main body arranged on the adapter circuit board and electrically connected to the M.2 connector; wherein the solid-state disk main body is adapted with and electrically connected to the USB connector via the M.2 connector and the adapter circuit board.

In comparison to the prior arts, the present invention is able to achieve at least the following technical effects: reducing purchase cost, distributing heat sources, and preventing re-insertion of gold finger provided on the solid-state disk main body with a limited time of insertions or preventing the number of times of insertions from exceeding the limit thereof.

### BRIEF DESCRIPTION OF DRAWING

FIG. 1 is a perspective view of the read/write console of the present invention viewed from the top;

FIG. 2 is a perspective view of the read/write console of the present invention viewed from the bottom;

FIG. 3 is a perspective exploded view of the solid-state disk assembly of the present invention;

FIG. 4 is another perspective exploded view of the solid-state disk assembly of the present invention;

FIG. 5 is a perspective assembly view of the solid-state disk assembly of the present invention;

FIG. 6 is a longitudinal cross-sectional view of the solid-state disk assembly of the present invention;

FIG. 7 is a lateral cross-sectional view of the solid-state disk assembly of the present invention;

FIG. 8 is a perspective view showing a state before the solid-state disk read/write apparatus of the present invention is inserted into the console;

FIG. 9 is a perspective view showing a state after the solid-state disk read/write apparatus of the present invention is inserted into the console; and

FIG. 10 is a perspective view of the read/write console according to another exemplary embodiment of the present invention.

### DETAILED DESCRIPTION OF THE INVENTION

The following provides a detailed technical content of the present invention along with the accompanied drawings. However, the accompanied drawings are provided for reference and illustrative purpose only such that they shall not be used to limit the scope of the present invention.

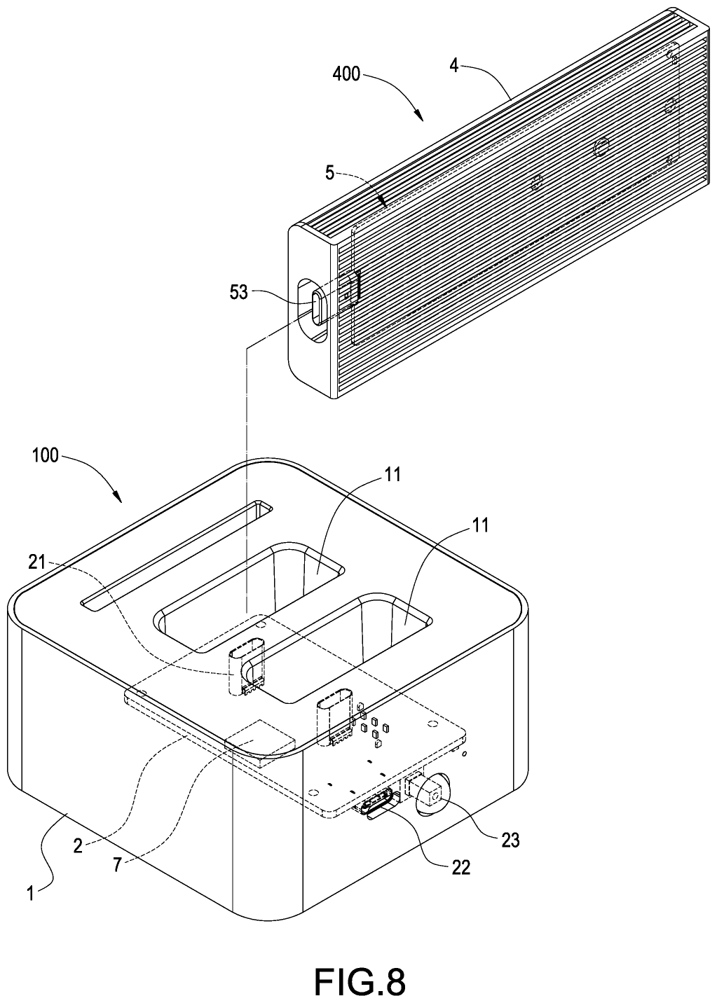

As shown in FIG. 8, the present invention provides a solid-state disk read/write apparatus and a solid-state disk assembly thereof. The solid-state disk read/write apparatus (referred to as the “read/write apparatus”) is provided to electrically connect to a processing device (as not shown in the drawings) in order to allow the processing device to process the data stored in the solid-state disk main body. The processing device can be any type of computer (such as desktop computer, notebook computer or tablet computer etc.), any type of home entertainment host machine (such as Microsoft Xbox One and SONY PS4 etc.) or any type of smartphone etc., and the present invention is not limited to any type of such devices. The read/write apparatus comprises a read/write console 100 and at least one solid state disk assembly 400 without a control chip.

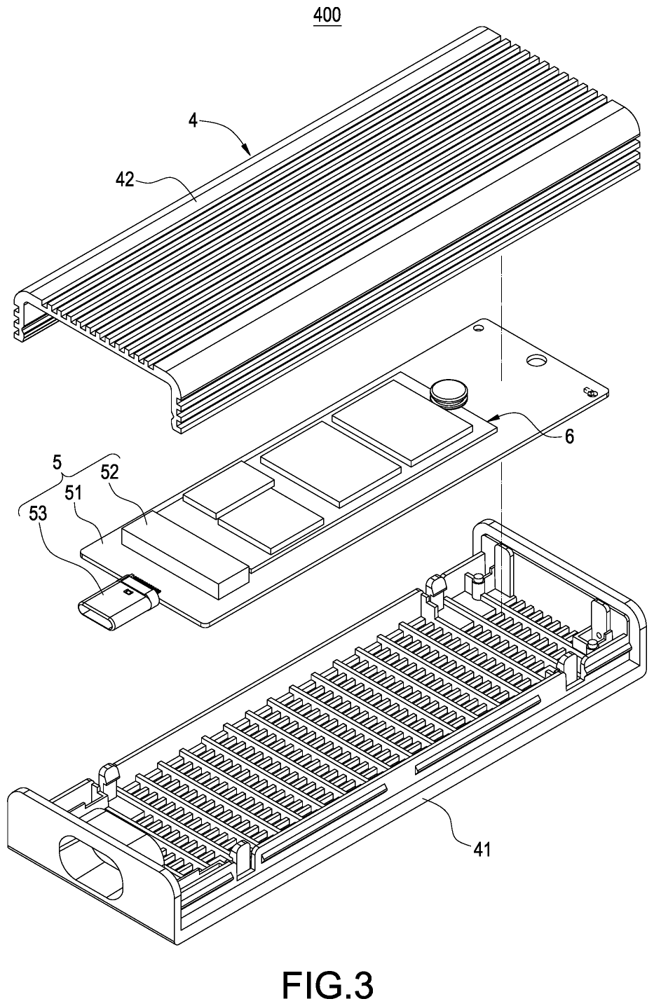

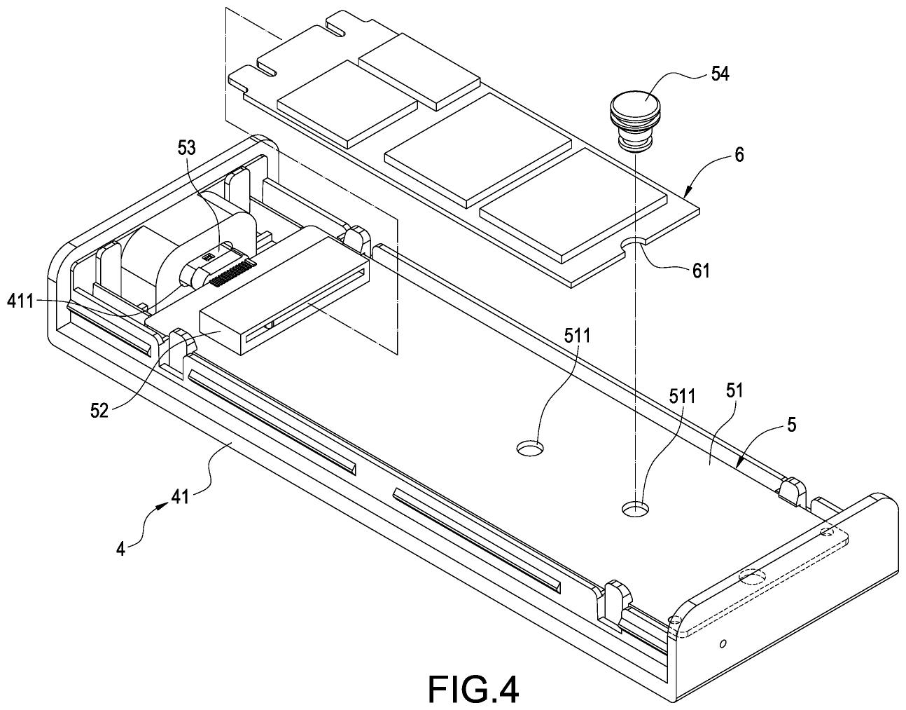

As shown in FIG. 3 to FIG. 5, the solid-state disk assembly 400 comprises a cassette 4, an adapter module 5 and a solid-state disk main body 6. In addition, the adapter module 5 is secured inside the cassette 4 and includes a M.2 connector 52 and a USB connector 53 electrically arranged (i.e.: arranged and electrically connected, same below) thereon. The USB connector 53 is exposed from the cassette 4. The solid-state disk main body (also known as the “solid-state disk naked drive”) 6 is electrically inserted onto the M.2 connector 52. The solid-state disk main body 6 is electrically inserted onto the M.2 connector 52 with the adaptive connection of the adapter module 5, thereby achieving the electrical connection with the USB connector 53.

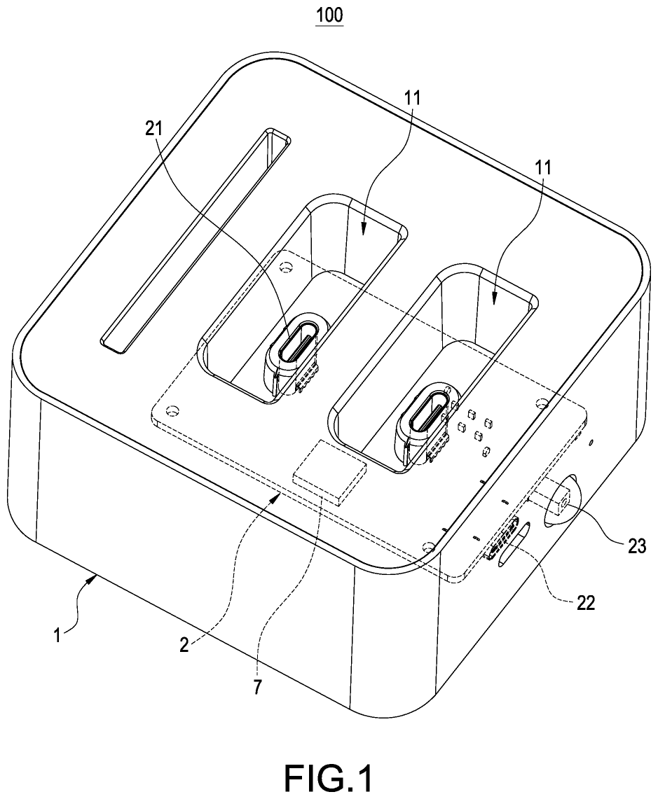

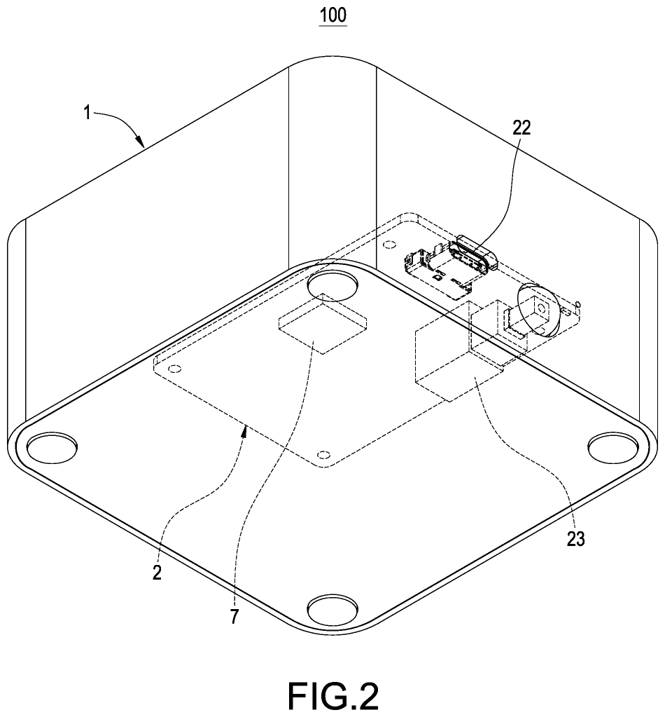

As shown in FIG. 1 to FIG. 2, the read/write console 100 comprises a circuit board 2. The circuit board 2 includes at least one USB engagement connector 21, a main connector 22 and a control chip 7 electrically arranged thereon. In an exemplary embodiment, the USB engagement connector 21 is provided with a plurality of connectors as an example for illustration. Accordingly, the cost of each solid-state disk assembly 400 can be significantly reduced as the control chip 7 accounted for approximately 37% of the total cost is changed to be configured on the read/write console 100 for share use (the cost ratio of the solid-state disk assembly 400 is much lower than that of a currently existing solid-state disk cassette).

The main connector 22 of the read/write console 100 can be electrically connected to the aforementioned processing device, such as with the use of a transmission cable connected therebetween; consequently, it is able to allow the processing device to process the data in the solid-state disk assembly 400 via the read/write console 100. In addition, it is also able to save external data into the solid-state disk assembly 400 via the read/write console 100.

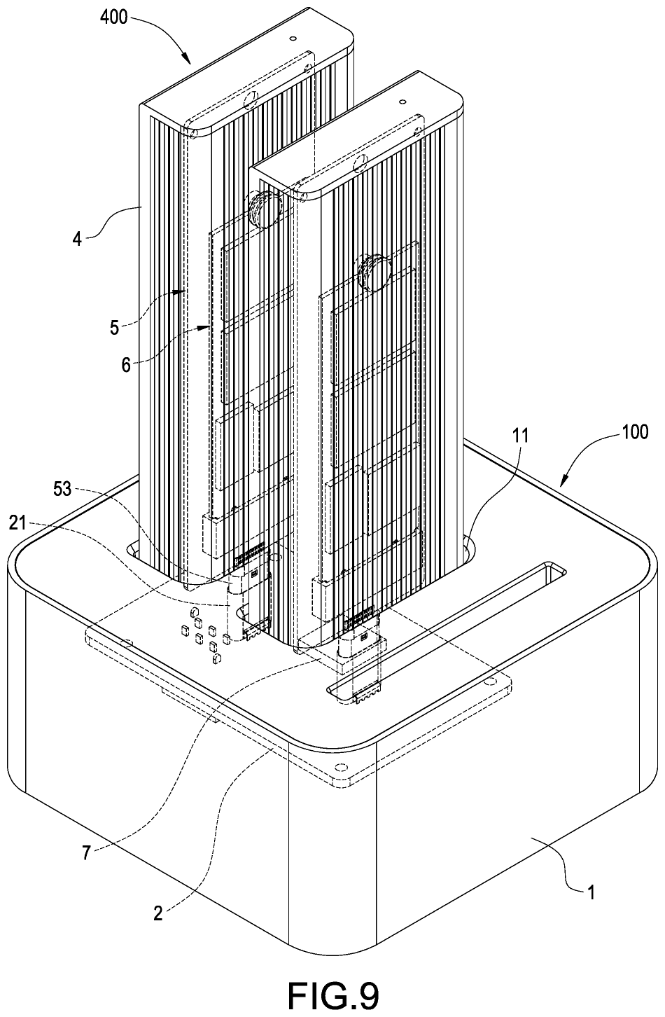

As shown in FIG. 8 and FIG. 9, as a result, users are only required to removably insert the USB connector 53 of the solid-state disk assembly 400 onto the USB engagement connector 21 of the read/write console 100, the solid-state disk main body 6 can then be electrically connected to the read/write console 100 via the adapter module 5 and the control chip 7 of the read/write console 100. In other words, since the control chip 7 is changed to be configured on the read/write console 100, it is able to significantly reduce the cost of the solid-state disk assembly 400, and users are required to only purchase one unit of read/write console 100 equipped with the control chip 7 in order to allow a plurality of solid-state disk assemblies 400 without the control chips installed therein to share the use of such one console; therefore, the purchase cost can be reduced.

Secondly, since there is no need to perform multiple times of removal and insertion on the M.2 connector 52 for different selection and use of solid-state disk main bodies 6, the limited times of insertion of gold finger would not be exceeded, and the issue of improper connection can be prevented.

Thirdly, two heat sources are separated from each other accordingly: the solid-state disk main body 6 and the control chip 7 are respectively allocated onto the solid-state disk assembly 400 and the read/write console 100, such that the heat sources are distributed and separated. Consequently, it is able to overcome the issue of heat accumulation from two heat sources, thereby improving the heat dissipation. In addition, as the solid-state disk main body 6 is prevented from operating under the environment of high temperature, the useful lifetime of the solid-state disk main body 6 can be prolonged.

Fourthly, since the read/write console 100 and the solid-state disk assembly 400 use the USB engagement connector 21 and the USB connector 53 having extensive durability in the limitation for number of times of insertion, they are of extremely high durability. In an exemplary embodiment, the USB connector 53 and the USB engagement connector 21 are a USB Type-C connector and a USB Type-C engagement connector respectively.

As shown in FIG. 1 and FIG. 2, the read/write console 100 comprises a base 1 and the aforementioned circuit board 2 installed inside the base 1. The base 1 includes a plurality of slots 11 formed thereon. Each USB engagement connector is exposed inside each positioning slot 11. The circuit board 2 further comprises a switch 23 electrically arranged thereon in order to control whether the read/write console 100 is to be switched on.

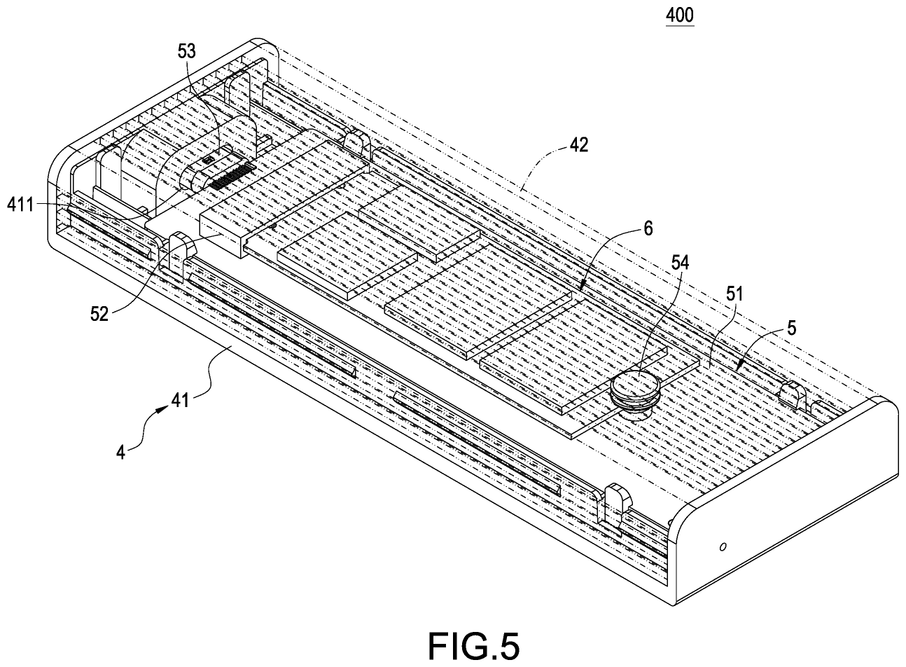

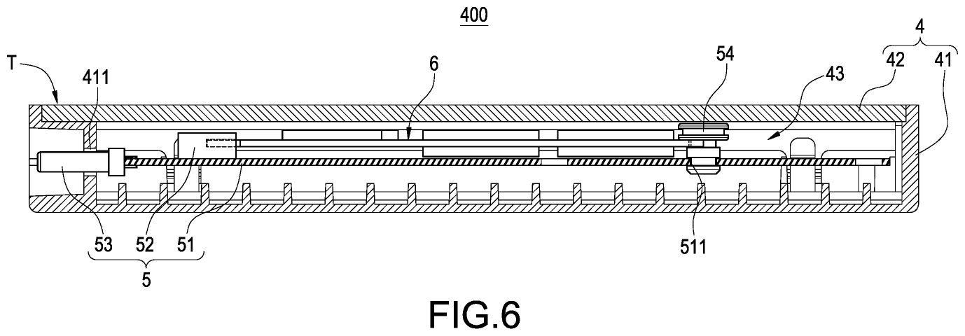

As shown in FIG. 5 and FIG. 6, the USB connector 53 is exposed out of an end portion of the solid-state disk assembly 400.

As shown in FIG. 8 and FIG. 9, accordingly, the solid-state disk assembly 400 can be removably inserted into the positioning slot 11 and is able to facilitate the USB connector 53 to be electrically inserted onto the USB engagement connector 21 at the same time. Preferably, the shape of the positioning slot 11 corresponds to the shape of the end portion T of the solid-state disk assembly 400; therefore, after the solid-state disk assembly 400 is inserted into the positioning slot 11, a stable positioning effect without any looseness or wobble can be achieved.

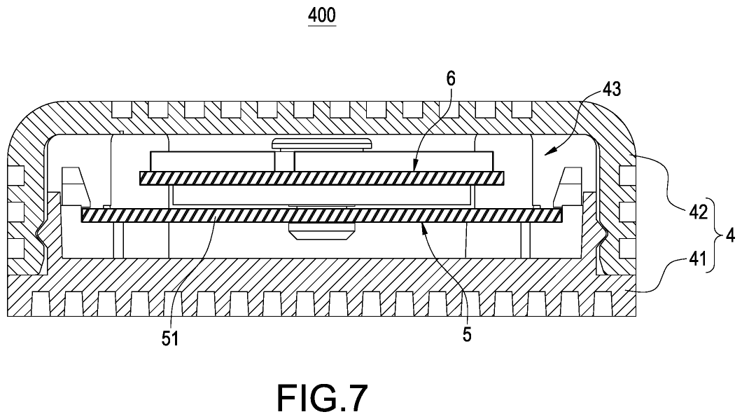

As shown in FIG. 3 to FIG. 7, in the solid-state disk assembly 400, the cassette 4 includes an accommodating space 43 formed therein, and the cassette 4 further includes an opening hole 411 fluidly connected to the accommodating space 43. The aforementioned adapter module 5 and the solid-state disk main body 6 are jointly received inside the accommodating space 43. The USB connector 53 penetrates through the opening hole 411 in order to allow the USB connector 53 to be exposed out of the cassette 4 via the opening hole 411.

Preferably, the cassette 4 comprises a cassette base 41 and a cassette cover 42. The cassette cover 42 is detachably locked onto the cassette base 41 in order to form the assembly thereof. The aforementioned accommodating space 43 is formed between the cassette base 41 and the cassette cover 42.

The adapter module 5 comprises an adapter circuit board 51 and the aforementioned M.2 connector 52 and the USB connector 53 electrically arranged on the adapter circuit board 51. The adapter circuit board 51 is secured inside the cassette 4, and the M.2 connector 52 is electrically arranged on one side of the adapter circuit board 51. The USB connector 53 is electrically arranged on and protruded at an edge of the adapter circuit board 51. The solid-state disk main body 6 is arranged on the same side of the adapter circuit board 51. In addition, the head portion of the solid-state disk main body 6 is electrically inserted onto the M.2 connector 52. Accordingly, the solid-state disk main body 6 can be adapted with and electrically connected to the USB connector 53 via the M.2 connector 52 and the adapter circuit board 51.

Furthermore, regarding the method for securing the solid-state disk main body 6 onto the adapter circuit board 51, the adapter circuit board 51 includes a plurality of fixation holes 511 formed thereon, and the rear end of the solid-state disk main body 6 includes a notch 61 formed thereon in order to use a fixation member 54 to insert into one of the fixation holes 511 corresponding to the notch 61, thereby securing the solid-state disk main body 6 between the M.2 connector 52 and the fixation member 54. In other words, the solid-state disk main body 6 is secured onto the adapter circuit board 51.

In addition, as shown in FIG. 8, the end portion T of the solid-state disk assembly 400 can further include a concave portion (not indicated with a reference numeral in the drawings) formed to indent inward, and an outer diameter of the USB connector 53 is smaller than an inner diameter of the concave portion. Furthermore, the USB connector 53 does not protrude out of the end portion T; in other words, it does not protrude out of the cassette 4. Consequently, it is able to achieve the effect of protecting the USB connector 53 from breakage due to external collision.

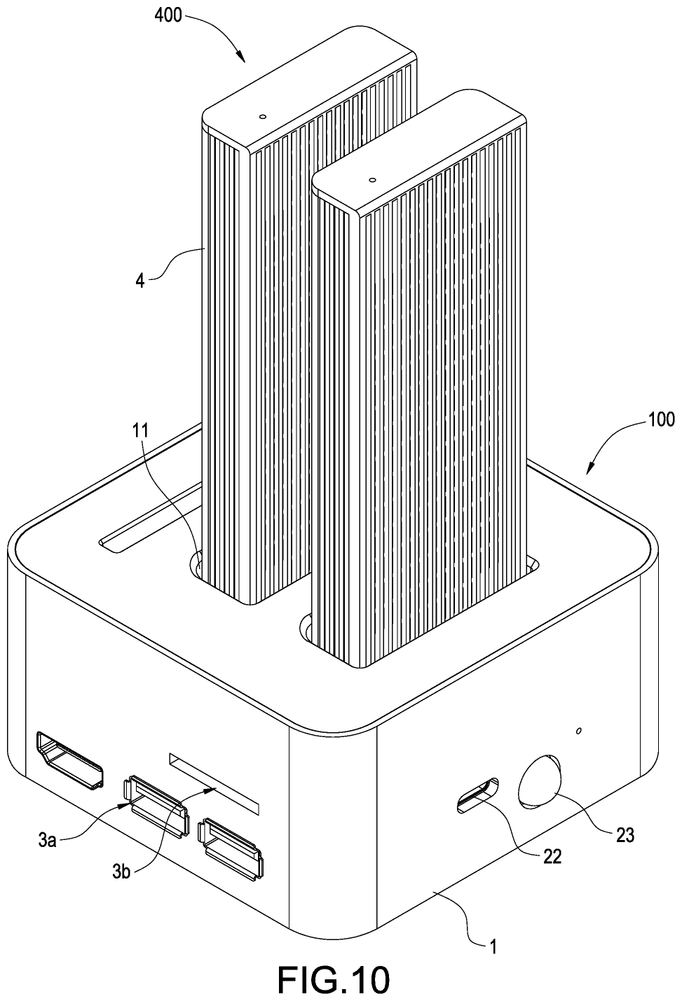

As shown in FIG. 10, the read/write console 100 can further comprise other connector 3a electrically arranged on the circuit board 2 (as shown in FIG. 1), or a card read/write unit 3b electrically arranged thereon, or the other connector 3a and the card read/write unit 3b electrically arranged thereon. The other connector 3a can be a USB connector other than USB Type-C; for example, the other connector 3a can be a HDMI connector. The card read/write unit 3b can be a card reader for SD card or Micro SD card.

In view of the above, a solid-state disk read/write apparatus and a solid-state disk assembly of the present invention is able to achieve the objectives of the present invention and to overcome the drawbacks of known arts. The present invention is novel and of inventive step, which satisfies the patentability requirements.

The above describes the preferable and feasible exemplary embodiments of the present invention for illustrative purposes only, which shall not be treated as limitations of the scope of the present invention. Any equivalent changes and modifications made in accordance with the scope of the claims of the present invention shall be considered to be within the scope of the claim of the present invention.

What is claimed is:

1. A solid-state disk read/write apparatus, comprising:
a solid-state disk assembly (400) comprising a cassette (4), a solid-state disk main body (6) and an adapter module (5); the adapter module (5) secured inside the cassette (4) and having a M.2 connector (52) and a USB connector (53); the solid-state disk main body (6) electrically inserted onto the M.2 connector (52) for adapting with and electrically connected to the USB connector (53); and
a read/write console (100) having a circuit board (2), and the circuit board (2) having a control chip (7) and at least one USB engagement connector (21) electrically arranged thereon;
wherein when the solid-state disk assembly (400) is removably and electrically inserted onto the USB engagement connector (21) of the read/write console (100) with the USB connector (53), the solid-state main body (6) is electrically connected to the read/write console (100) via the adapter module (5) and the control chip (7).

2. The solid-state disk read/write apparatus according to claim 1, wherein the USB connector (53) and the USB engagement connector (21) are a USB Type-C connector and a USB Type-c engagement connector respectively.

3. The solid-state disk read/write apparatus according to claim 1, wherein the circuit board (2) of the read/write console (100) further comprises a main connector (22) electrically arranged thereon; the main connector (22) is arranged to be electrically connected with a processing device in order to process data of the solid-state disk main body (6).

4. The solid-state disk read/write apparatus according to claim 1, wherein the read/write console (100) includes at least one positioning slot (11) formed thereon; the at least one USB engagement connector (21) is exposed in the at least one positioning slot (11); the USB connector (53) is exposed at one end portion of the solid-state disk assembly (400); the solid-state disk assembly (400) is removably inserted into the positioning slot (11) with the end portion in order to facilitate the USB connector (53) to be electrically connected onto the USB engagement connector (21).

5. The solid-state disk read/write apparatus according to claim 1, wherein the read/write console (100) further comprises at least one other connector (3a) electrically arranged on the circuit board (2), at least one card read/write unit (3b) electrically arranged thereon, or at least one other connector (3a) and at least one card read/write device (3b) electrically arranged thereon.

6. A solid-state disk assembly (400), comprising:
a cassette (4);
an adapter module (5) comprising an adapter circuit board (51), a M.2 connector (52) and a USB connector (53); the adapter circuit board (51) secured inside the cassette (4); the M.2 connector (52) and the USB connector (53) electrically arranged on the adapter circuit board (51); the USB connector (53) exposed out of the cassette (4); and
a solid-state disk main body (6) arranged on the adapter circuit board (51) and electrically connected to the M.2 connector (52);
wherein the solid-state disk main body (6) is adapted with and electrically connected to the USB connector (53) via the M.2 connector (52) and the adapter circuit board (51).

7. The solid-state disk assembly (400) according to claim 6, wherein the cassette (4) comprises a cassette base (41) and a cassette cover (42); the cassette cover (42) is detachably locked onto the cassette box (41) in order to form an accommodating space (43) between the cassette cover (42) and the cassette base (41); the solid-state disk main body (6) and the adapter module (5) are jointly received inside the accommodating space (43).

8. The solid-state disk assembly (400) according to claim 7, wherein the cassette base (41) further includes an opening hole (411) formed thereon; the opening hole (411) is fluidly connected to the accommodating space (43), and the USB connector (53) is exposed out of the cassette (4) via the opening hole (411).

9. The solid-state disk assembly (400) according to claim 6, further comprising a fixation member (54); the adapter circuit board (51) includes a plurality of fixation holes (511) formed thereon; the solid-state disk main body (6) includes a notch (61); the solid-state disk main body (6) is inserted onto one of the fixation holes (511) with the fixation member (54) arranged corresponding to the notch (61) in order to be secured onto the adapter circuit board (51).

10. The solid-state disk assembly (400) according to claim 6, wherein the M.2 connector (52) is arranged on one side of the adapter circuit board (51); the USB connector (53) is arranged on and protruded at an edge of the adapter circuit board (51); the solid-state disk main body (6) is arranged on the one side of the adapter circuit board (51).
